(19) United States
(12) Patent Application Publication
(10) Pub. No.: US 2011/0260179 A1
(43) Pub. Date: Oct. 27, 2011

(54) FLEXIBLE LED PACKAGING STRUCTURE

(75) Inventor: Chia-Chien HUNG, New Taipei City (TW)

(73) Assignee: ChengFeng Electro-optical Limited Company, New Taipei City (TW)

(21) Appl. No.: 13/075,432

(22) Filed: Mar. 30, 2011

(30) Foreign Application Priority Data
Apr. 21, 2010 (TW) 099207265

(51) Int. Cl. H01L 33/08; H01L 33/62

(52) U.S. Cl. 257/88; 257/99; 257/E33.065; 257/E33.056

(57) ABSTRACT

A flexible LED packaging structure includes two or more metal foil substrates. One or more LED chips are assembled onto the primary metal foil substrate by silver glue or solder paste or eutectic. A secondary metal foil substrate is electrically connected with the LED chip by wires or eutectic. There is a spacing between the primary and secondary metal foil substrates. A packaging colloid, made of a flexible material, is fully covered onto the LED chip and partially covered onto the primary and secondary metal foil substrates, such that the lower surface of the primary and secondary metal foil substrates is exposed. With this principle, a plurality of LEDs is electrically connected in parallel or in series, and the metal foil substrate could be used to improve the heat-radiating effect, thus enabling flexible assembly onto multiple lightings.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates generally to LED packaging technology, and more particularly to an innovative one which has a metal foil substrate for the diode chip, so as to increase the heat-radiating efficiency based on a flexible LED packaging structure made of flexible packaging colloid.

2. Description of Related Art Including Information Disclosed Under 37 CFR 1.97 and 37 CFR 1.98

LEDs (Light Emitting Diode) are now used in a wide range of applications with rapid technological development. For instance, LED lights are set as the display backlights, indoor/outdoor electronic billboards or lightings in various occasions.

As a general rule, a plurality of LEDs are used simultaneously to enhance the brightness of light source. However, a heat-radiating problem is encountered. The substrate of conventional LED packaging structure is generally made of PCB or ceramics, making it difficult for heat dissipation or failure or even burning of the light-emitting elements.

The conventional LED packaging structure is generally designed into a non-flexible pattern for mating with various lamps.

Thus, to overcome the aforementioned problems of the prior art, it would be an advancement if the art to provide an improved structure that can significantly improve the efficacy.

Therefore, the inventor has provided the present invention of practicability after deliberate experimentation and evaluation based on years of experience in the production, development and design of related products.

### BRIEF SUMMARY OF THE INVENTION

For the aforementioned problems, the purpose of the present invention is to provide an LED with improved heat-radiating efficiency, and to apply flexible packaging colloid to metal foil substrate such that the packaged LED is a flexible structure for assembling onto various lightings.

The present invention provides a flexible LED packaging structure, which includes two or more metal foil substrates. One or more LED chips are assembled onto the primary metal foil substrate by silver glue or solder paste or eutectic. Secondary metal foil substrate is electrically connected with LED chip by wires or eutectic, of which, there is a spacing between the primary and secondary metal foil substrates. A packaging colloid, made of a flexible material, is fully covered onto the LED chip and partially covered onto the primary and secondary metal foil substrates, such that the lower surface of the primary and secondary metal foil substrates is exposed.

The flexible LED packaging structure of the present invention allows a metal foil substrate to support the diode chip. As the heat-radiating efficiency is improved substantially, it can be widely applied to high-power or a plurality of LED lights. Moreover, the flexible packaging colloid and metal foil substrate allows for bending and assembling into various lightings, thus improving the applicability of the present invention. Meanwhile, the aforementioned advantages can also be exploited when the LED chips are used in parallel or in series.

### BRIEF DESCRIPTION OF THE SEVERAL VIEWS OF THE DRAWINGS

FIGS. 1-6 are schematic views of a preferred embodiment for a single LED packaging structure.

FIG. 1 is a schematic view of an LED packaging structure with two electrodes at the front.

FIG. 2 is a schematic view of a flexible LED packaging structure with two electrodes at the front.

FIG. 3 is a schematic view of an LED packaging structure with an electrode at the front and the other one at the back.

FIG. 4 is a schematic view of a flexible LED packaging structure with an electrode at the front and the other one at the back.

FIG. 5 is a schematic view of an LED packaging structure with two electrodes at the back.

FIG. 6 is a schematic view of a flexible LED packaging structure with two electrodes at the back.

FIGS. 7-12 are schematic views of a preferred embodiment for a packaging structure with several LEDs in parallel.

FIG. 7 is a schematic view of packaging structure with several LEDs in parallel and two electrodes at the front.

FIG. 8 is a schematic view of a flexible packaging structure with several LEDs in parallel and two electrodes at the front.

FIG. 9 is a schematic view of a packaging structure with several LEDs in parallel as well as an electrode at the front and the other one at the back.

FIG. 10 is a schematic view of a flexible packaging structure with several LEDs in parallel as well as an electrode at the front and the other one at the back.

FIG. 11 is a schematic view of a packaging structure with several LEDs in parallel and two electrodes at the back.

FIG. 12 is a schematic view of a flexible packaging structure with several LEDs in parallel and two electrodes at the back.

FIGS. 13-18 are schematic views of a preferred embodiment for a packaging structure with several LEDs in series.

FIG. 13 is a schematic view of a packaging structure with several LEDs in series and two electrodes at the front.

FIG. 14 is a schematic view of a flexible packaging structure with several LEDs in series and two electrodes at the front.

FIG. 15 is a schematic view of a packaging structure with several LEDs in series as well as an electrode at the front and the other one at the back.

FIG. 16 is a schematic view of a flexible packaging structure with several LEDs in series as well as an electrode at the front and the other one at the back.

FIG. 17 is a schematic view of a packaging structure with several LEDs in series and two electrodes at the back.

FIG. 18 is a schematic view of a flexible packaging structure with several LEDs in series and two electrodes at the back.

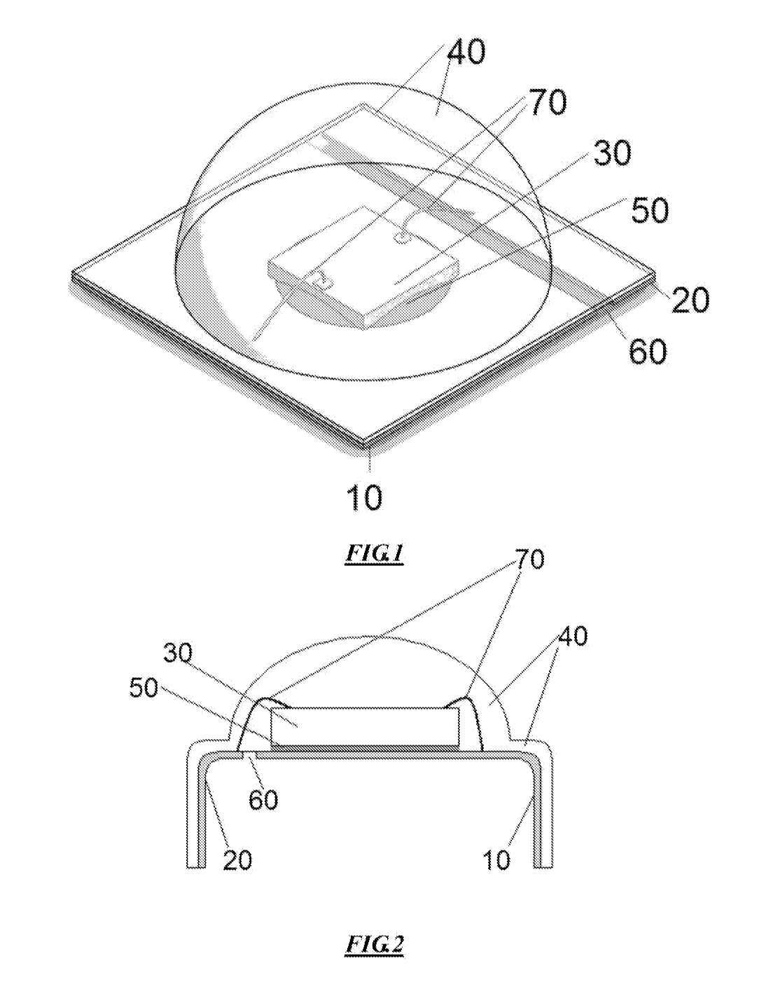

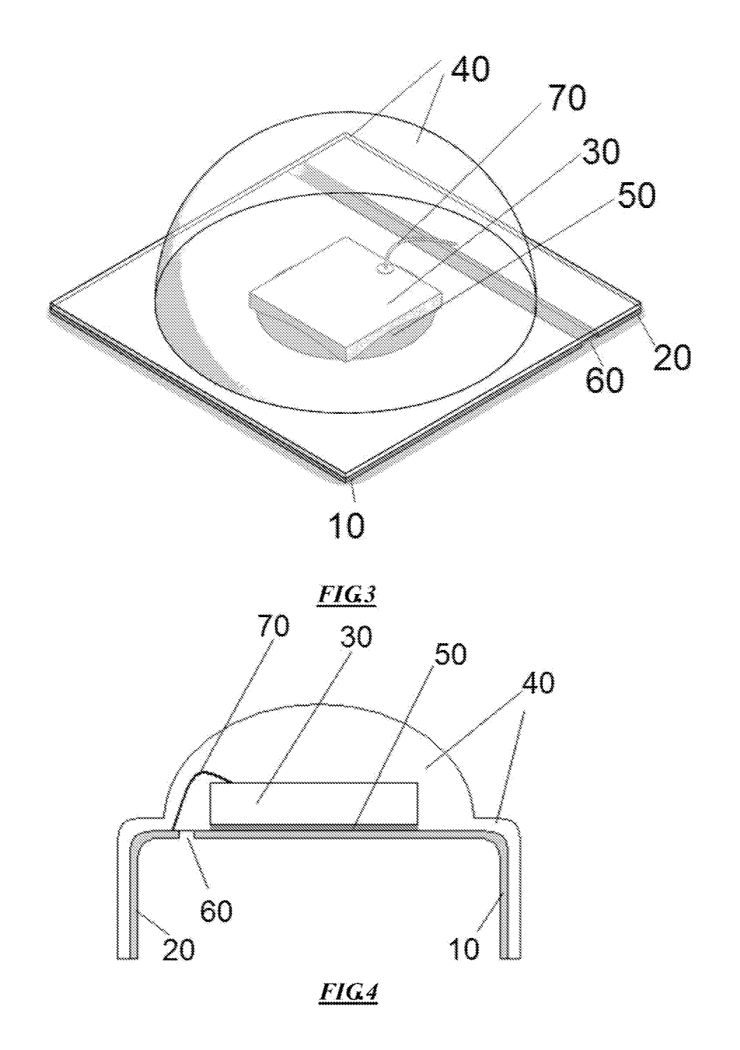

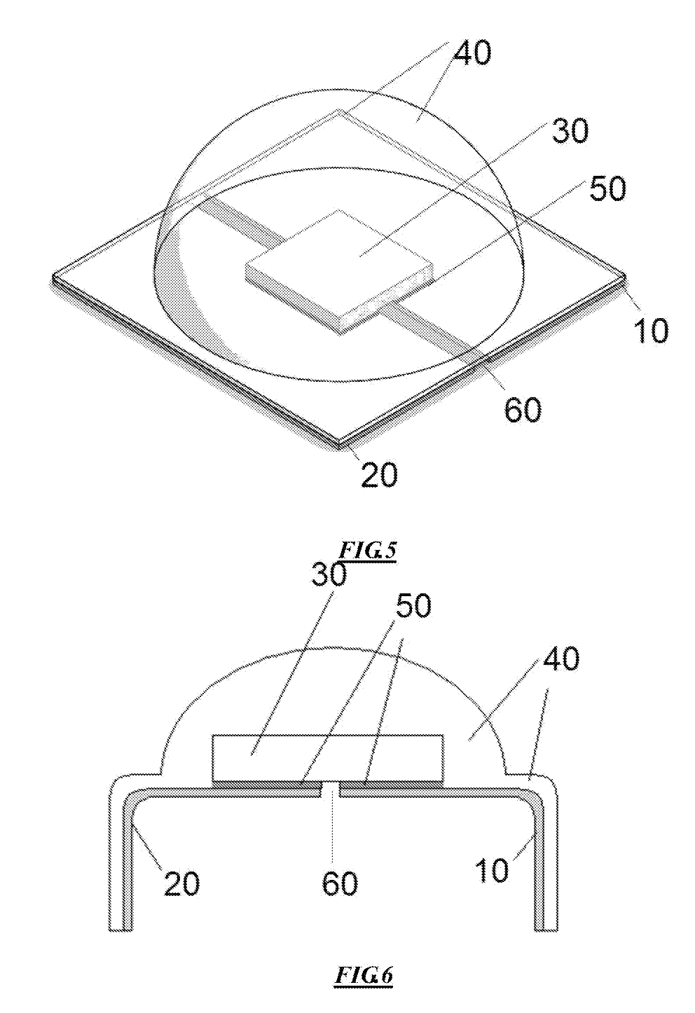

### DETAILED DESCRIPTION OF THE INVENTION

The contents of the present invention will be more readily understood upon a thoughtful deliberation of the following detailed description of the present invention with reference to the accompanying drawings.

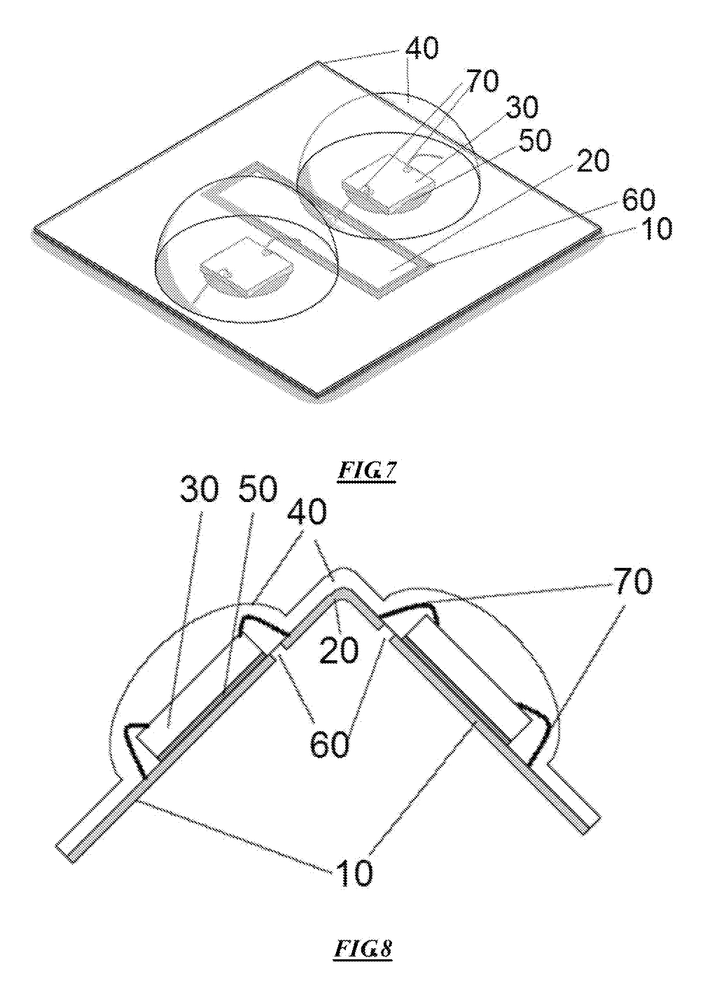

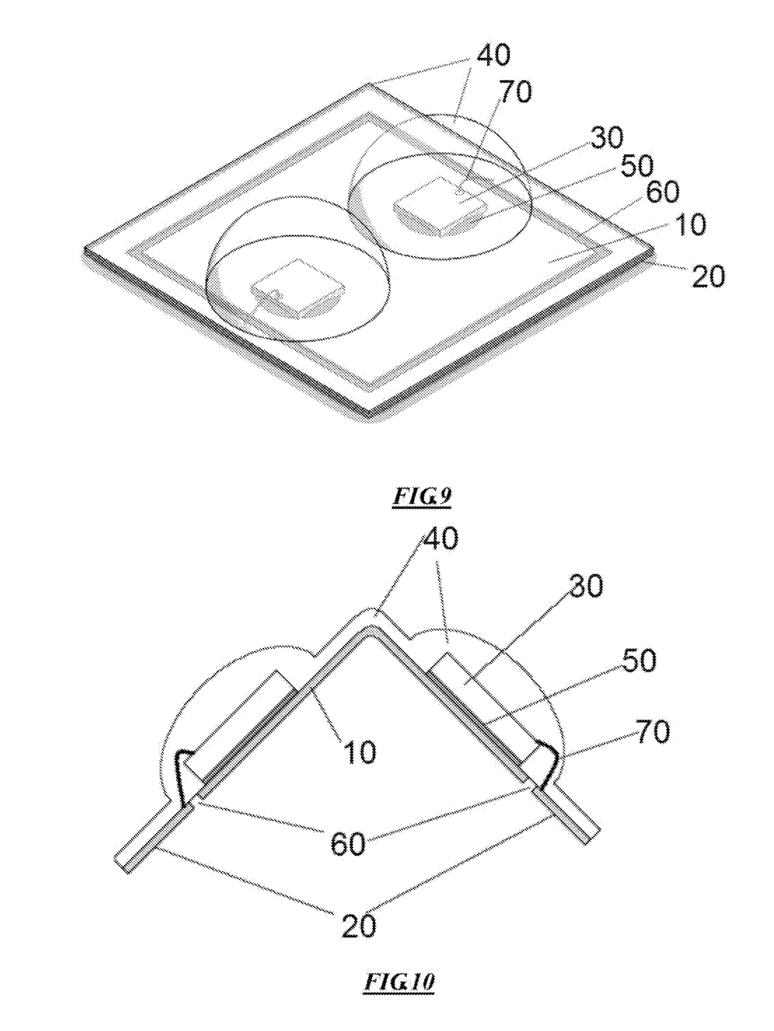

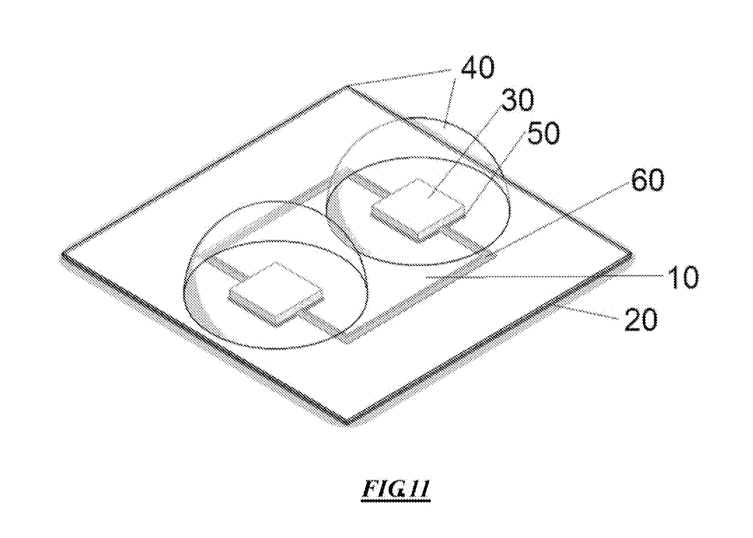

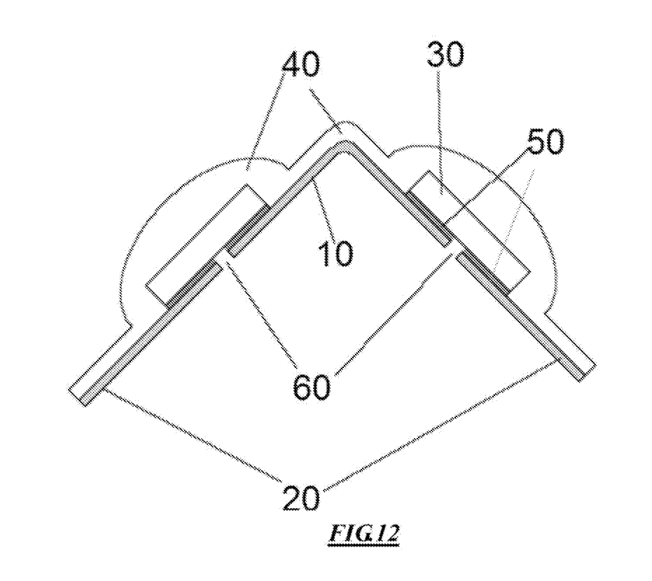

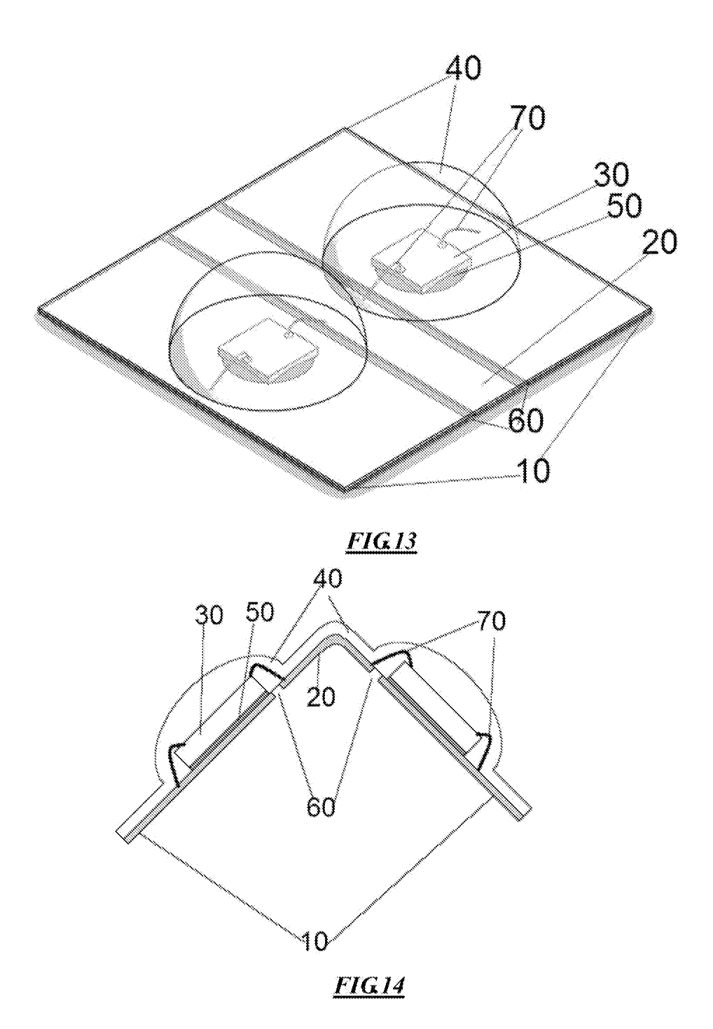

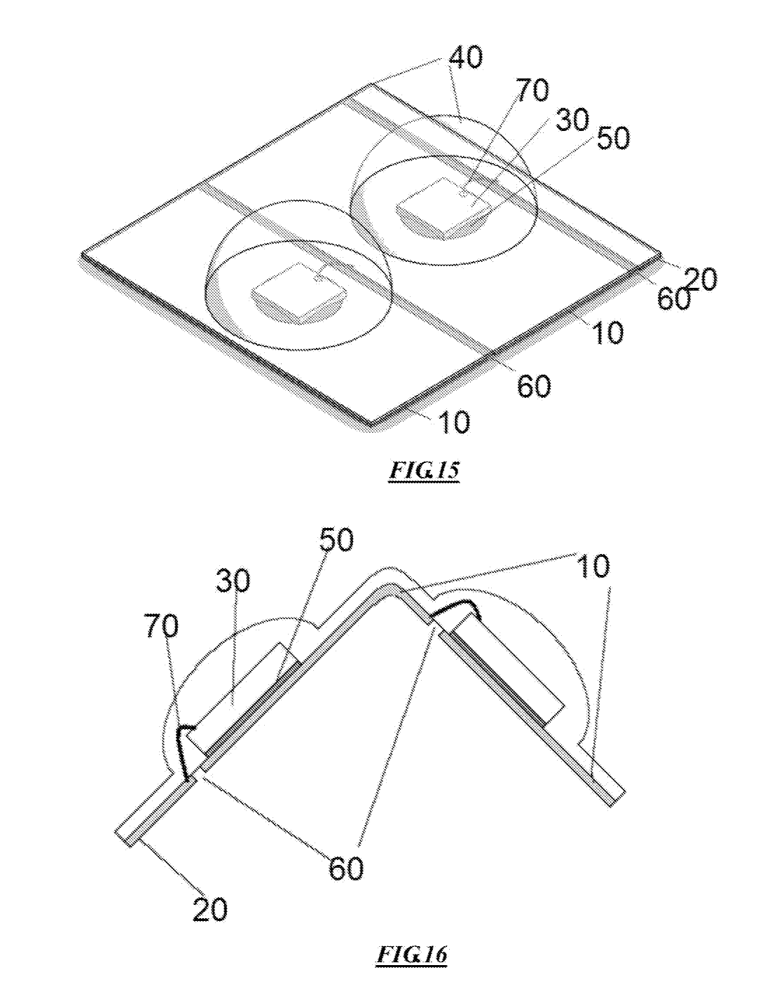

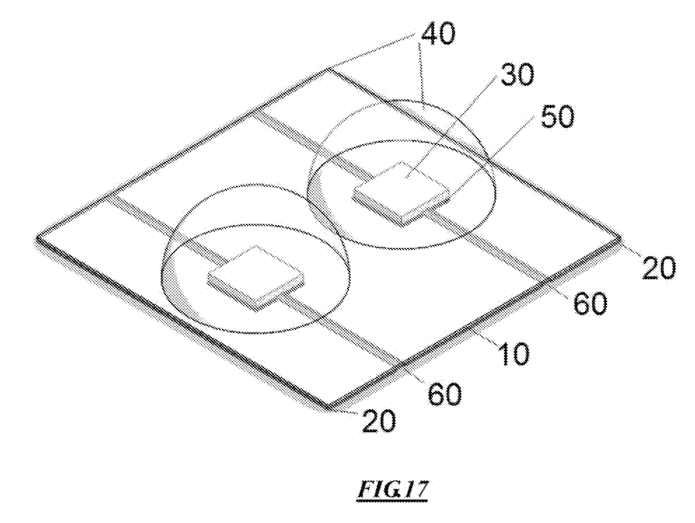

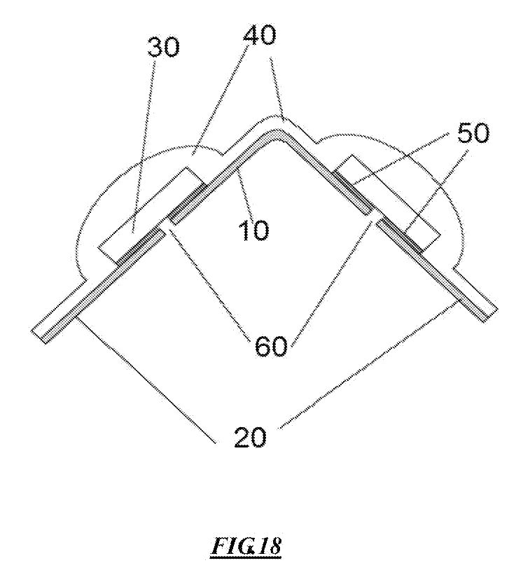

FIGS. 1, 7 and 13 show the preferred embodiments of the present invention. FIG. 1 illustrates a packaging structure with a single LED, FIG. 7 illustrates a packaging structure with multiple LEDs in parallel, and FIG. 13 illustrates a packaging structure with multiple LEDs in series. The flexible LED packaging structure of the present invention includes one or more primary metal foil substrates 10, one or more LED chips 30, one or more secondary metal foil substrates 20 and a packaging colloid 40. The primary metal foil substrate 10 is used to support the LED chip 30. A bonding layer 50 is used to bond securely the LED chip 30 onto the primary metal foil substrate 10. Besides, the metal foil substrate is made of metals of excellent conductivity, such as aluminum or copper, so as to enhance the heat-radiating effect of LEDs. Moreover, the secondary metal foil substrate 20 is electrically connected with the LED chip 30 by the welding wire 70 or eutectic. Of which, there is a spacing 60 between the primary metal foil substrate 10 and secondary metal foil substrate 20, such that the primary and secondary metal foil substrates 10, 20 can be used independently as positive and negative electrodes. The packaging colloid 40 made of flexible material is not fully covered onto the primary and secondary metal foil substrates 10, 20, so that the lower surface of the primary and secondary metal foil substrates 10, 20 is exposed to external heat sink or electrodes, and the current can be conducted for better heat-radiating effect. The LED chip 30 is fully covered into packaging colloid 40 for protection purposes.

Additionally, the bonding layer 50 may be bonded by silver glue or solder paste or eutectic, so as to enhance the robustness of the LED chip 30, and increase efficiently heat conduction to the primary and secondary metal foil substrates 10, 20.

The efficacy of the present invention lies in that, the flexible LED packaging structure allows a metal foil substrate to support the diode chip, thereby improving substantially the heat-radiating efficiency. It can be widely applied to high-power or a plurality of LED lights. Moreover, the flexible packaging colloid allows for bending and assembling into various lightings, thus improving the applicability of the present invention. Meanwhile, the aforementioned advantages can also be exploited when the LED chips are used in parallel or in series.

Although the invention has been explained in relation to its preferred embodiment, it is to be understood that many other possible modifications and variations can be made without departing from the spirit and scope of the invention as hereinafter claimed.

1. A flexible LED packaging structure; comprising:
a primary metal foil substrate;
an LED chip, bonded onto the primary metal foil substrate by a bonding layer;
a secondary metal foil substrate; electrically connected with the LED chip by welding wire or eutectic; of which, there is a spacing between the primary and secondary metal foil substrate; and
a packaging colloid, made of a flexible material, fully covered onto the LED chip and partially covered onto the primary and secondary metal foil substrates.

2. A flexible packaging structure with LEDs in parallel comprising:
two or more LED chips, bonded onto a primary metal foil substrate by a bonding layer;
one or more secondary metal foil substrates, electrically connected with said LED chip by wires or eutectic, of which, there is a spacing between the primary and secondary metal foil substrates; and
a packaging colloid, made of a flexible material, fully covered onto the LED chip and partially covered onto the primary and secondary metal foil substrates.

3. A flexible packaging structure with LEDs in series comprising:
two or more LED chips, bonded onto a primary metal foil substrate by a bonding layer;
one or more secondary metal foil substrates, electrically connected with said LED chip by wires or eutectic, of which, there is a spacing between the primary and secondary metal foil substrates; and
a packaging colloid, made of a flexible material, fully covered onto the LED chip and partially covered onto the primary and secondary metal foil substrates.

4. The structure of claim 1, applied to an DC or AC LED packaging structure.
